(19) United States
(12) Patent Application Publication
(10) Pub. No.: US 2023/0178477 A1
(43) Pub. Date: Jun. 8, 2023

(54) SEMICONDUCTOR DEVICE AND METHOD FOR FABRICATING THE SEMICONDUCTOR DEVICE

(71) Applicant: Samsung Electronics Co., Ltd., Suwon-si (KR)

(72) Inventors: Anthony Dongick LEE, Hwaseong-si (KR); Sang Cheol NA, Seoul (KR); Seo Woo NAM, Seoul (KR); Ki Chul PARK, Suwon-si (KR)

(73) Assignee: Samsung Electronics Co., Ltd., Suwon-si (KR)

(21) Appl. No.: 17/866,917

(22) Filed: Jul. 18, 2022

(30) Foreign Application Priority Data
Dec. 8, 2021 (KR) 10-2021-0174447

(51) Int. Cl. H01L 23/522; H01L 23/532; H01L 23/528; H01L 21/768

(52) U.S. Cl. CPC H01L 23/5226; H01L 21/76816; H01L 21/76843; H01L 21/76877; H01L 23/5283; H01L 23/53238

(57) ABSTRACT

A semiconductor device is provided. The semiconductor device comprises a first wiring structure which includes a first material, and has a first width on a lowest surface in a first direction and a second wiring structure which includes a second material, is spaced apart from the first wiring structure in the first direction, and has a second width smaller than the first width on a lowest surface in the first direction, wherein a highest surface of the first wiring structure has a third width smaller than the first width in the first direction, and a highest surface of the second wiring structure has a fourth width smaller than the second width in the first direction.

### CROSS-REFERENCE TO RELATED APPLICATION

This application claims priority from Korean Patent Application No. 10-2021-0174447 filed on Dec. 8, 2021 in the Korean Intellectual Property Office, and all the benefits accruing therefrom under 35 U.S.C. 119, the contents of which in its entirety are herein incorporated by reference.

### BACKGROUND

Various example embodiments relate to a semiconductor device and/or a method for fabricating the semiconductor device, and more specifically, to a semiconductor device including a wiring line formed in a BEOL (Back-End-Of-Line) process, and/or a method for fabricating the semiconductor device.

As down-scaling of semiconductor elements has progressed rapidly in recent years with development of electronic technology, there is a demand or a desire for higher integration and lower power consumption of semiconductor chips. The feature size of semiconductor devices continues to decrease to satisfy the demand and desire for higher integration and/or lower power consumption of the semiconductor chips.

On the other hand, as the feature size decreases, various studies are being conducted on stable connection methods between the wirings.

### SUMMARY

Aspects of various example embodiments provide a semiconductor device capable of improving element performance and/or reliability.

Aspects of various example embodiments also provide a method for fabricating a semiconductor device capable of fabricating a semiconductor device having improved product reliability.

According to some example embodiments, there is provided a semiconductor device comprising a first wiring structure which includes a first material, and has a first width on a lowest surface in a first direction, and a second wiring structure which includes a second material, is spaced apart from the first wiring structure in the first direction, and has a second width smaller than the first width on a lowest surface in the first direction. A highest surface of the first wiring structure has a third width less than the first width in the first direction, and a highest surface of the second wiring structure has a fourth width less than the second width in the first direction.

According to some example embodiments, there is provided a semiconductor device comprising a first wiring structure which includes a first material and has a first width on a lowest surface in a first direction, a second wiring structure which includes a second material, is spaced apart from the first wiring structure in the first direction, and has a second width smaller than the first width on a lowest surface in the first direction, and an upper via connected onto the first wiring structure. The lowest surface of the first wiring structure and the lowest surface of the second wiring structure are coplanar, and a highest surface of the first wiring structure is above a highest surface of the second wiring structure.

According to some example embodiments, there is provided a semiconductor device comprising an interlayer insulating film defining a first trench and a second trench, a width of a bottom surface of the first trench being smaller than a width of a bottom surface of the second trench, a first wiring structure inside the first trench and including an upper surface coplanar with an upper surface of the interlayer insulating film and a second wiring structure inside the second trench and including an upper surface below an upper surface of the interlayer insulating film. A width of the bottom surface of the first trench is greater than a width of a highest part of the first trench, and a width of the bottom surface of the second trench is greater than a width of a highest part of the second trench.

According to some example embodiments, there is provided a method for fabricating a semiconductor device, the method comprising forming a first material film including a first region and a second region, removing the first material film inside the first region, sequentially forming a barrier film and a filling film in the first region from which the first material film is removed, forming a first wiring structure whose width increases from a highest surface toward a lowest surface, forming an insulating pattern on the second region of the first material film, patterning the first material film using the insulating pattern to form a second wiring structure whose width increases from a highest surface toward a lowest surface and forming a wiring capping film having an upper surface coplanar with the highest surface of the first wiring structure, on the second wiring structure,. A width of the lowest surface of the first wiring structure is greater than a width of the lowest surface of the second wiring structure.

However, aspects of various example embodiments are not restricted to the one set forth herein. The above and other aspects of various example embodiments will become more apparent to one of ordinary skill in the art to which various example embodiments pertains by referencing the detailed description of various example embodiments given below.

### BRIEF DESCRIPTION OF THE DRAWINGS

The above and other aspects and features of various example embodiments will become more apparent by describing in detail various example embodiments thereof with reference to the attached drawings, in which:

FIG. 1 is an example layout diagram for explaining the semiconductor device according to some example embodiments.

FIG. 2 is an example cross-sectional view taken along A-A of FIG. 1.

FIG. 3 is an example cross-sectional view taken along B-B of FIG. 1.

FIG. 4 is an example cross-sectional view taken along C-C of FIG. 1.

FIGS. 5 to 8 are diagrams for explaining a semiconductor device according to some example embodiments.

FIG. 10 is a diagram for explaining the semiconductor device according to some example embodiments.

FIG. 11 is a diagram for explaining the semiconductor device according to some example embodiments.

FIGS. 12 to 24 are intermediate step diagrams for explaining a method for fabricating a semiconductor device according to some example embodiments.

### DETAILED DESCRIPTION OF VARIOUS EXAMPLE EMBODIMENTS

Although drawings of a semiconductor device according to some example embodiments show a fin-type transistor (FinFET) including a channel region of a fin-type pattern shape, a transistor including a nanowire or a nanosheet or a MBCFET™ (Multi-Bridge Channel Field Effect Transistor) as an example, embodiments are not limited thereto. The semiconductor device according to some example embodiments may alternatively or additionally include one or more of a tunneling transistor (tunneling FET) or a three-dimensional (3D) transistor. The semiconductor device according to some example embodiments may, include a planar transistor. In addition, the technical idea of various example embodiments may be applied to a transistor based on two-dimensional material (2D material based FETs) and a heterostructure thereof.

Further, the semiconductor device according to some example embodiments may alternatively or additionally include one or more of a bipolar junction transistor, a laterally diffused metal oxide semiconductor (LDMOS), or the like.

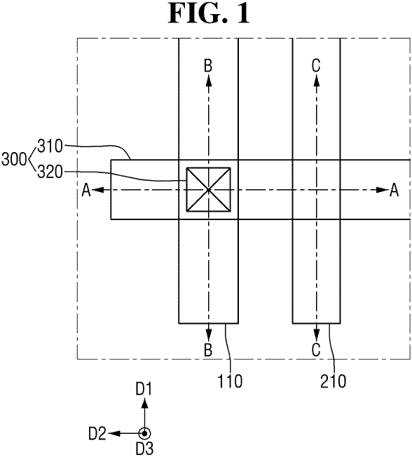

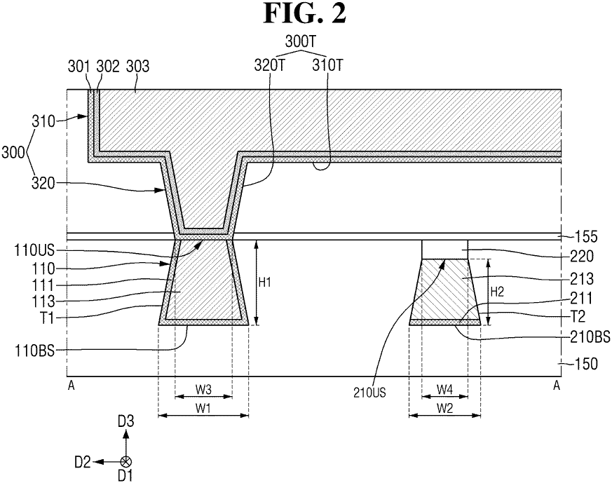

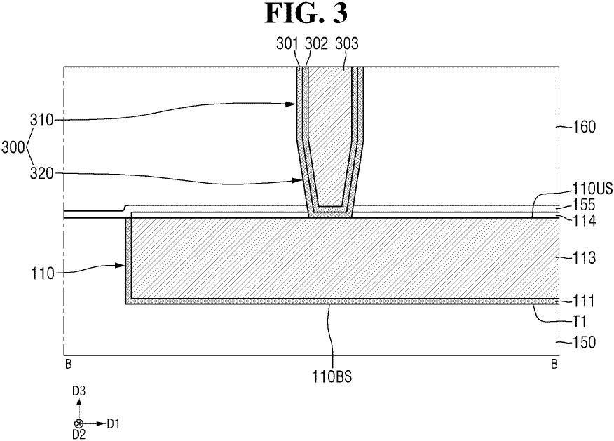

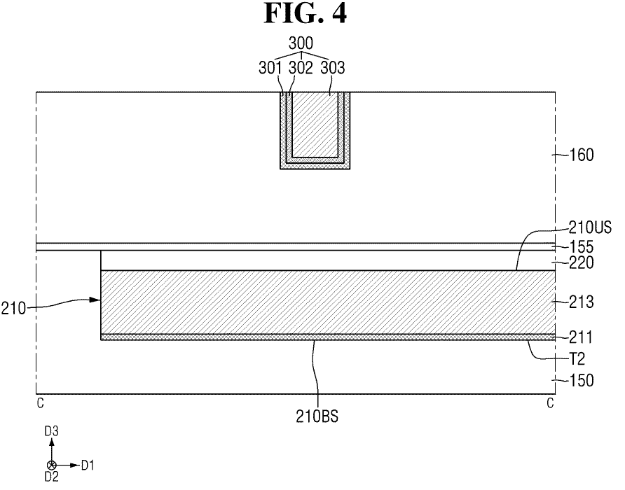

FIG. 1 is an example layout diagram for explaining the semiconductor device according to various example embodiments. FIG. 2 is an example cross-sectional view taken along A-A of FIG. 1. FIG. 3 is an example cross-sectional view taken along B-B of FIG. 1. FIG. 4 is an example cross-sectional view taken along C-C of FIG. 1.

Referring to FIGS. 1 to 4, the semiconductor device according to some example embodiments may include a first wiring structure 110, a second wiring structure 210, and an upper wiring structure 300.

The first wiring structure 110 may be placed inside a first interlayer insulating film 150. The first wiring structure 110 may extend along in a first direction D1.

The first wiring structure 110 may have a line or linear shape extending in the first direction D1. For example, the first direction D1 may be a length direction of the first wiring structure 110, and the second direction D2 may be a width direction of the first wiring structure 110. Here, the first direction D1 intersects a second direction D2 and a third direction D3. The second direction D2 intersects the third direction D3. The first direction D1, the second direction D2, and the third direction D3 may be orthogonal to one another; however, example embodiments are not limited thereto.

The first interlayer insulating film 150 may cover a gate electrode and/or a source/drain of a transistor formed in a FEOL (Front-end-of-Line) process. Alternatively, the first interlayer insulating film 150 may be an interlayer insulating film formed in a BEOL (Back-end-of-line) process.

For example, the first wiring structure 110 may be a contact or contact wiring/local interconnect formed in a MOL (middle-of-line) process. As another example, the first wiring structure 110 may be a connection wiring formed in the BEOL (Back-end-of-line) process. In the following description, the first wiring structure 110 will be described as a connection wiring formed in the BEOL process; however, example embodiments are not limited thereto.

The first interlayer insulating film 150 may include, for example, at least one of silicon oxide, silicon nitride, silicon oxynitride and a low dielectric constant material. The low dielectric constant material may be, for example, silicon oxide having moderately high carbon and hydrogen, and may be a material such as SiCOH. On the other hand, since carbon is included in the insulating material, the dielectric constant of the insulating material may be lowered. However, in order to further reduce the dielectric constant of the insulating material, the insulating material may include a pore such as a cavity in which (inert) gas and/or air is filled in the insulating material.

The low dielectric constant material may include, for example, but is not limited to, one Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethyleyCloTetraSiloxane (OMCTS), HexaMethylDiSiloxane (HMDS), TriMethylSilyl Borate (TMSB), DiAcetoxyDitertiaryButoSiloxane (DADBS), TriMethylSilil Phosphate (TMSP), PolyTetraFluoroEthylene (PTFE), TOSZ (Tonen SilaZen), FSG (Fluoride Silicate Glass), polyimide nanofoams such as polypropylene oxide, CDO (Carbon Doped silicon Oxide), OSG (Organo Silicate Glass), SiLK, Amorphous Fluorinated Carbon, silica aerogels, silica xerogels, mesoporous silica or combinations thereof.

The first wiring structure 110 may be placed at a first metal level. The first interlayer insulating film 150 may include a first trench T1 extending long in the first direction D1.

The first wiring structure 110 may be placed inside the first trench T1. The first wiring structure 110 fills the first trench T1.

The first wiring structure 110 may include a first barrier film 111 and a first filling film 113.

The first barrier film 111 may extend along sidewalls and a bottom surface of the first trench T1.

The first filling film 113 is placed on the first barrier film 111 inside the first trench T1. The first filling film 113 may fill the rest of the first trench T1. The first filling film 113 may include a first material different from the second material included in the second filling film 213, and may not include the second material. In some example embodiments, the first material included in the first filling film 113 may include copper (Cu) and may not include ruthenium (Ru).

The first barrier film 111 includes a conductive material, and may include, for example, a metal nitride. The first barrier film 111 may include, for example, at least one of tantalum nitride (TaN), titanium nitride (TiN), tungsten nitride (WN), zirconium nitride (ZrN), vanadium nitride (VN), and niobium nitride (NbN). In the following description, the first barrier film 111 will be described as including tantalum nitride (TaN).

The first filling film 113 may include a conductive material, and may include, for example, at least one of aluminum (Al), copper (Cu), tungsten (W), cobalt (Co), ruthenium (Ru), silver (Ag), gold (Au), manganese (Mn), molybdenum (Mo), rhodium (Rh), iridium (Ir), RuAl, NiAl, NbB₂, MoB₂, TaB₂, V₂AlC and CrAlC. In the semiconductor device according to some example embodiments, the first filling film 113 may include copper (Cu).

A lower capping film 114 may extend along an upper surface 110US of the first wiring structure. The lower capping film 114 may be placed on the first filling film 113.

The lower capping film 114 may not cover the upper surface of the first barrier film 111. Unlike the shown example, the lower capping film 114 may cover at least a part of the upper surface of the first barrier film 111.

The lower capping film 114 includes a conductive material, and may include, for example, a metal. The lower capping film 114 may include, for example, at least one of cobalt (Co), ruthenium (Ru) and manganese (Mn). In the semiconductor device according to some example embodiments, the lower capping film 114 may include cobalt. The lower capping film 114 may be made of cobalt (Co).

Unlike the shown example, the first wiring structure 110 may have a single film structure. Although not shown, a via pattern that connects the conductive patterns placed below the first wiring structure 110 may be further included.

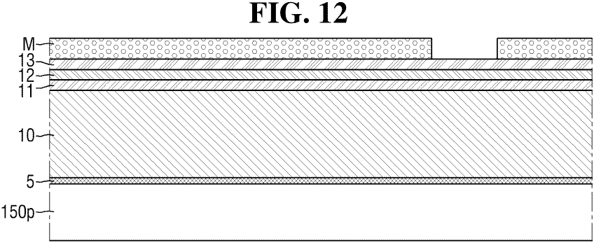

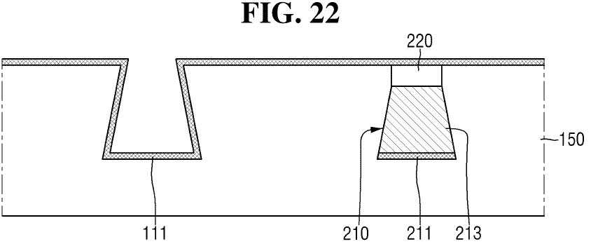

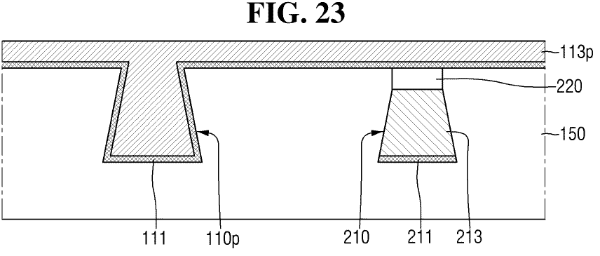

The first wiring structure 110 may be formed, for example, using a subtractive process such as a damascene process and/or a dual damascene process. Specifically, the pre-wiring structure formed using the subtractive process may be removed to form the first trench T1, and the first wiring structure 110 may be formed in the first trench T1. This will be specifically described referring to FIGS. 12 to 24.

The first wiring structure 110 may have a trapezoidal cross section, e.g., an upside-down trapezoidal cross-section with one edge connected to two other edges at obtuse angles. Specifically, a width of a lower surface 110BS of the first wiring structure may be greater than a width of the upper surface 110US of the first wiring structure. In some example embodiments, the lower surface 110BS of the first wiring structure may have a first width W1. For example, the width of the bottom surface of the first trench T1 in the second direction D2 may have the first width W1.

The upper surface 110US of the first wiring structure may have a third width W3. For example, the highest part of the first trench T1 may have the third width W3. As used herein, the “highest” may refer to a plane that is parallel to but furthest from an upper surface of a substrate. The width of the highest part of the first trench T1 in the second direction D2 may be the third width W3. At this time, the first width W1 is greater than the third width W3. For example, the width of the first wiring structure 110 may decrease from the lower surface 110BS of the first wiring structure toward the upper surface 110US of the first wiring structure.

The first wiring structure 110 may have a first height H1. At this time, the height of the first wiring structure 110 may refer to a distance from the lower surface 110BS of the first wiring structure to the upper surface 110US of the first wiring structure. For example, the distance between the upper surface 110US of the first wiring structure and the lower surface 110BS of the first wiring structure may be the first height H1.

The first width W1 of the lower surface 110BS of the first wiring structure is greater than the second width W2 of the lower surface 210BS of the second wiring structure. For example, the first width W1 in the second direction D2 of the lower surface 110BS of the first wiring structure is greater than the second width W2 in the second direction D2 of the lower surface 210BS of the second wiring structure.

The upper surface 110US of the first wiring structure may be coplanar with, or placed on the same plane as, the upper surface of the first interlayer insulating film 150. The lower surface 110BS of the first wiring structure is coplanar with or placed on the same plane as the lower surface 210BS of the second wiring structure.

The first height H1 of the first wiring structure 110 is greater than the second height H2 of the second wiring structure 210. For example, the first height H1, which is the distance from the lower surface 110BS of the first wiring structure to the upper surface 110US of the first wiring structure, is greater than the second height H2 which is the distance from the lower surface 210BS of the second wiring structure to the upper surface 210US of the second wiring structure.

Although the first wiring structure 110 is shown as including, but is not limited to, the first barrier film 111 and the first filling film 113, either or both of which may not be included. Alternatively or additionally, unlike the shown example, a hard mask pattern may be placed along the upper surface of the first filling film 113 Alternatively or additionally, a passivation film may be placed along the sidewall of the first filling film 113, unlike the shown example. Alternatively or additionally, the first barrier film 111 may be omitted. Alternatively or additionally, the first barrier film 111 may include, for example, at least one of a metal nitride, a metal, a metal carbide, and a two-dimensional material (2D material). The two-dimensional material may be a metallic material and/or a semiconductor material. The two-dimensional (2D material) may include a two-dimensional allotrope or a two-dimensional compound, and may include, but is not limited to, for example, at least one of graphene, molybdenum disulfide (MoS₂), molybdenum diselenide (MoSe₂), tungsten diselenide (WSe₂), and tungsten disulfide (WS₂). For example, since the above-mentioned two-dimensional materials are only listed by way of example, the two-dimensional materials that may be included in the semiconductor device of various example embodiments are not limited by the above-mentioned materials.

The first wiring structure 110 may be connected to the upper wiring line 310. Specifically, the first wiring structure 110 may be placed below the upper wiring line 310. The first wiring structure 110 may be placed below the upper via 320. The first wiring structure 110 may be connected or directly connected to the upper via 320. The first wiring structure 110 may be connected to the upper wiring line 310 through the upper via 320.

The first etching stop film 155 may be placed on the first wiring structure 110, the first interlayer insulating film 150, and the second wiring structure 210. Specifically, the lower surface of the first etching stop film 155 may be coplanar with or placed on the same plane as the upper surface 110US of the first wiring structure. The plane may be parallel to an upper surface of a substrate. The first etching stop film 155 may be placed on the wiring capping film 220. The lower surface of the first etching stop film 155 may come into contact with the wiring capping film 220. The lower surface of the first etching stop film 155 may be coplanar with or placed on the same plane as the upper surface of the wiring capping film 220.

The second interlayer insulating film 160 may be coplanar with or placed on the first etching stop film 155. The first etching stop film 155 may be placed between the first interlayer insulating film 150 and the second interlayer insulating film 160.

The second interlayer insulating film 160 may include or define an upper wiring trench 300T. The upper wiring trench 300T may pass through the first etching stop film 155. The upper wiring trench 300T may expose a part of the first wiring structure 110.

The second wiring structure 210 may be placed at the first metal level together with the first wiring structure 110. The second wiring structure 210 may be spaced apart from the first wiring structure 110 in the second direction D2. The first interlayer insulating film 150 may include or define a second trench T2 extending long in the first direction D1.

The second wiring structure 210 may be placed inside the first interlayer insulating film 150. The second wiring structure 210 may extend long in the first direction D1.

The second wiring structure 210 may have a line shape extending in the first direction D1. For example, the first direction D1 may be the length direction of the second wiring structure 210, and the second direction D2 may be the width direction of the second wiring structure 210.

The second wiring structure 210 may be placed inside the second trench T2. The second wiring structure 210 fills the second trench T2.

The second wiring structure 210 may include a second barrier film 211 and a second filling film 213.

The second barrier film 211 may extend along the bottom surface of the second trench T2. The second barrier film 211 may not extend along the sidewall of the second trench T2. For example, the second wiring structure 210 includes the second barrier film 211 placed on the bottom surface inside the second trench T2, and the second barrier film 211 is not placed on the side part of the second trench T2. Therefore, the sidewall of the second wiring structure 210 may be in direct contact with the first interlayer insulating film 150. Specifically, since the first barrier film 111 is placed on the side part of the first wiring structure 110, the first filling film 113 may not be in contact with or direct contact with the first interlayer insulating film 150. On the other hand, since the second barrier film 211 is not placed on the side of the second wiring structure 210, the second filling film 213 may be in direct contact with the first interlayer insulating film 150.

The second filling film 213 may be placed on the second barrier film 211 inside the second trench T2. The second filling film 213 may fill the rest of the second trench T2. The second filling film 213 may include a second material different from the first material included in the first filling film 113. In some example embodiments, the second material included in the second filling film 213 may include ruthenium (Ru) and may not include copper (Cu)—.

The second filling film 213 includes a conductive material, and may include, for example, at least one of aluminum (Al), copper (Cu), tungsten (W), cobalt (Co), ruthenium (Ru), silver (Ag), gold (Au), manganese (Mn), molybdenum (Mo), rhodium (Rh), iridium (Ir), RuAl, NiAl, NbB₂, MoB₂, TaB₂, V₂A1C and CrAlC. In the semiconductor device according to some example embodiments, the second filling film 213 may include ruthenium (Ru).

The second wiring structure 210 may be formed, for example, using a subtractive process. Specifically, after forming a conductive film serving as a base material of the second wiring structure 210, a mask pattern is formed on the conductive film. The conductive film is etched, using the mask pattern as a mask. Accordingly, the second wiring structure 210 may be formed. This will be described in more detail when referring to FIGS. 12 to 24.

The second wiring structure 210 may have a trapezoidal cross section. Specifically, the width of the lower surface 210BS of the second wiring structure may be greater than the width of the upper surface 210US of the second wiring structure. In some example embodiments, the lower surface 210BS of the second wiring structure may have a second width W2. For example, the width of the bottom surface of the second trench T2 in the second direction D2 may have the second width W2.

The upper surface 210US of the second wiring structure may have a fourth width W4. For example, the highest part of the second trench T2 may have the fourth width W4. The width of the highest part of the second trench T2 in the second direction D2 may be the fourth width W4. At this time, the second width W2 is greater than the fourth width W4. That is, the width of the second wiring structure 210 may decrease from the lower surface 210BS of the second wiring structure toward the upper surface 210US of the second wiring structure.

The second wiring structure 210 may have a second height H2. At this time, the height of the second wiring structure 210 may refer to a distance from the lower surface 210BS of the second wiring structure to the upper surface 210US of the second wiring structure. The upper surface 210US of the second wiring structure may refer to a surface on which the second wiring structure 210 is in contact with the lower surface of the wiring capping film 220. For example, the distance between the upper surface 210US of the second wiring structure and the lower surface 210BS of the second wiring structure may be the second height H2.

The upper surface 210US of the second wiring structure is lower than the upper surface of the first interlayer insulating film 150. Specifically, since the wiring capping film 220 is placed on the second wiring structure 210, the upper surface 210US of the second wiring structure is located to be lower than the upper surface of the first interlayer insulating film 150 by the height of the wiring capping film 220.

The second width W2 of the lower surface 210BS of the second wiring structure is smaller than the first width W1 of the lower surface 110BS of the first wiring structure. For example, the second width W2 in the second direction D2 of the lower surface 210BS of the second wiring structure is greater than the first width W1 in the second direction D2 of the lower surface 110BS of the first wiring structure.

The lower surface 210BS of the second wiring structure and the lower surface 110BS of the first wiring structure are placed on the same plane.

The second height H2 of the second wiring structure 210 is smaller than the first height H1 of the first wiring structure 110. The upper surface 210US of the second wiring structure is lower than the upper surface 110US of the first wiring structure. For example, the second height H2, which is the distance from the lower surface 210BS of the second wiring structure to the upper surface 210US of the second wiring structure, is lower than the first height H1 which is the distance from the lower surface 110BS of the first wiring structure to the upper surface 110US of the first wiring structure.

The second wiring structure 210 is shown as including, but is not limited to, the second barrier film 211 and the second filling film 213, but may include neither, one, or the other and example embodiments are not limited thereto..

The second wiring structure 210 may not be directly connected to the upper wiring line 310. Specifically, the second wiring structure 210 may be placed below the upper wiring line 310 to be spaced apart from the upper wiring line 310 in the third direction D3. The second wiring structure 210 is not directly connected to the upper via 320.

The wiring capping film 220 may be placed on the second wiring structure 210. The wiring capping film 220 may extend along the first direction D1. The wiring capping film 220 may be in contact with the upper surface 210US of the second wiring structure. The wiring capping film 220 may be in contact with the second filling film 213. The lower surface of the wiring capping film 220 may be in contact with the upper surface 210US of the second wiring structure. The width of the lower surface of the wiring capping film 220 may be the same as the width of the upper surface 210US of the second wiring structure. For example the width of the lower surface of the wiring capping film 220 may have the fourth width W4. The wiring capping film 220 may include silicon nitride and may or may not include another material such as silicon oxide.

The upper surface of the wiring capping film 220 may be placed on the same plane as the upper surface 110US of the first wiring structure. The upper surface of the wiring capping film 220 may be placed on the same plane as the first interlayer insulating film 150.

The wiring capping film 220 may be placed below the first etching stop film 155. The upper surface of the wiring capping film 220 may come into contact with the lower surface of the first etching stop film 155. The upper surface of the wiring capping film 220 may be placed on the same plane as the lower surface of the first etching stop film 155.

The width of the wiring capping film 220 in the second direction D2 may be constant. For example, the wiring capping film 220 may have a square or rectangular cross section. Specifically, the wiring capping film 220 may have a constant width in the second direction D2 regardless of the distance from the upper surface 210US of the second wiring structure.

The wiring capping film 220 may be spaced apart from the upper wiring structure 300 in the third direction D3. Specifically, the wiring capping film 220 may not come into contact with the upper wiring structure 300. The wiring capping film 220 may not be directly connected to the upper wiring structure 300. The wiring capping film 220 may not be directly connected to the upper via 320.

The upper wiring structure 300 may be placed inside the upper wiring trench 300T. The upper wiring structure 300 may fill the upper wiring trench 300T. The upper wiring structure 300 may be placed in the second interlayer insulating film 160.

The upper wiring structure 300 is placed on the first wiring structure 110 and the second wiring structure 210. The upper wiring structure 300 is connected to the first wiring structure 110. The upper wiring structure 300 comes into contact with the first wiring structure 110.

The upper wiring structure 300 includes an upper wiring line 310 and an upper via 320. The upper via 320 connects the upper wiring line 310 and the first wiring structure 110. The upper via 320 comes into contact with the first wiring structure 110. The upper via 320 may come into contact with the upper surface 110US of the first wiring structure.

The upper wiring structure 300 fills the upper via trench 320T and the upper wiring line trench 310T. The upper wiring line 310 is placed inside the upper wiring line trench 310T. The upper via 320 is placed inside the upper via trench 320T.

The upper wiring line 310 is placed at a second metal level different from the first metal level. The upper wiring line 310 is placed at a second metal level higher than the first metal level.

The upper wiring structure 300 includes an upper barrier film 301, an upper liner 302, and an upper filling film 303. Although not shown, the upper wiring structure 300 may include an upper capping film that may have the same or similar composition as that of the lower capping film 114.

The upper barrier film 301 extends along the sidewall of the upper wiring trench 300T. The upper barrier film 301 extends along the bottom surface of the upper wiring trench 300T. The upper barrier film 301 may extend along the bottom surfaces of the upper wiring line trench 310T and the upper via trench 320T. The upper barrier film 301 may cover the first wiring structure 110 exposed by the upper via trench 320T.

The upper barrier film 301 extends along the sidewall and bottom surface of the upper wiring line trench 310T and the sidewall of the upper via trench 320T. The upper barrier film 301 extends to the first wiring structure 110 that defines the bottom surface of the upper wiring trench 320T.

In the semiconductor devices according to some example embodiments, the upper barrier film 301 extends to the upper surface of the first filling film 113. The upper barrier film 301 comes into contact with the upper surface of the first filling film 113. Further, the upper barrier film 301 may come into contact with the lower capping film 114 that defines the sidewall of the upper via trench 320T.

The upper barrier film 301 includes a conductive material, and may include, for example, a metal nitride. The upper barrier film 301 may include, for example, at least one of tantalum nitride (TaN), titanium nitride (TiN), tungsten nitride (WN), zirconium nitride (ZrN), vanadium nitride (VN), and niobium nitride (NbN). In the following description, the upper barrier film 301 will be described as being formed of tantalum nitride (TaN).

The upper liner 302 is placed on the upper barrier film 301. The upper liner 302 is placed between the upper barrier film 301 and the upper filling film 303. For example, the upper liner 302 may come into contact with the upper barrier film 301.

The upper liner 302 extends along the sidewall and bottom surface of the upper wiring trench 300T. The upper liner 302 extends along the sidewall and bottom surface of the upper wiring line trench 310T and along the sidewall and bottom surface of the upper via trench 320T.

The upper liner 302 may come into contact with the first wiring structure 110. The upper liner 302 comes into contact with the upper surface of the first filling film 113. The upper liner 230 extends along the upper surface of the first filling film 113. The upper liner 302 may come into contact with the first barrier film 111.

The upper filling film 303 is placed on the upper liner 302. The upper filling film 303 may come into contact with the upper liner 302. The upper filling film 303 may fill the rest of the upper wiring trench 300T.

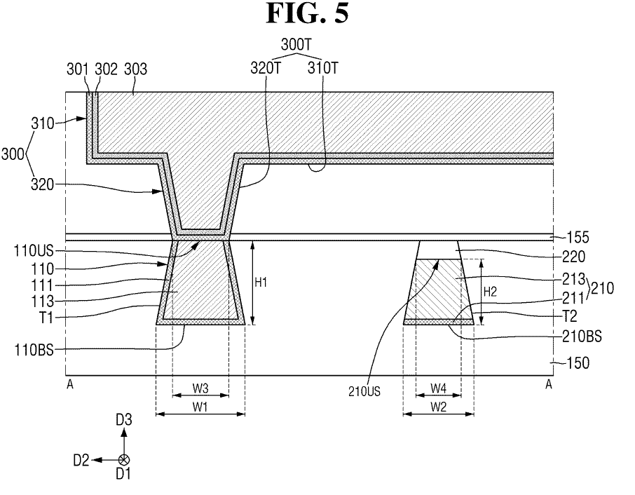

FIGS. 5 to 9 are diagrams for explaining a semiconductor device according to some example embodiments. For convenience of explanation, the points different from those described referring to FIGS. 1 to 4 will be mainly described.

Referring to FIG. 5, the wiring capping film 220 may not have a constant width along the third direction D3. Specifically, the width of the wiring capping film 220 in the second direction D2 may decrease as it goes away from the upper surface 210US of the second wiring structure in the third direction D3. The wiring capping film 220 may have a width which is greater than the fourth width W4 of the upper surface 210US of the second wiring structure on the lower surface and is smaller than the fourth width W4 on the upper surface.

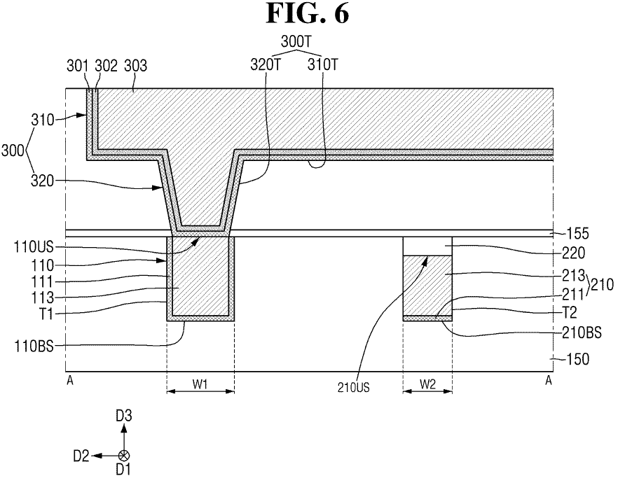

Referring to FIG. 6, the widths of the first wiring structure 110 and the second wiring structure 210 may be constant in the second direction D2. For example, the first wiring structure 110 may have a rectangular cross section.

The first wiring structure 110 may have a first width W1 on the lower surface 110BS of the first wiring structure, and may also have the first width W1 on the upper surface 110US. The width of the first wiring structure 110 in the second direction D2 may be constant from the lower surface 110BS of the first wiring structure to the upper surface 110US of the first wiring structure along the third direction D3. At this time, the constant first width W1 of the first wiring structure 110 is greater than the constant second width W2 of the second wiring structure 210.

The second wiring structure 210 may have a second width W2 on the lower surface 210BS of the second wiring structure, and may also have the second width W2 on the upper surface 210US. The width of the second wiring structure 210 in the second direction D2 may be constant from the lower surface 210BS of the second wiring structure to the upper surface 210US of the second wiring structure along the third direction D3. At this time, the constant second width W2 of the second wiring structure 210 is smaller than the constant first width W1 of the first wiring structure 110.

The width of the wiring capping film 220 placed on the second wiring structure 210 may be constant along the third direction D3. Specifically, on the lower surface on which the wiring capping film 220 is in contact with the upper surface 210US of the second wiring structure, the wiring capping film 220 may have a second width W2 in the second direction D2. Further, on the upper surface on which the wiring capping film 220 is in contact with the first etching stop film 155, the wiring capping film 220 may have a second width W2 in the second direction D2.

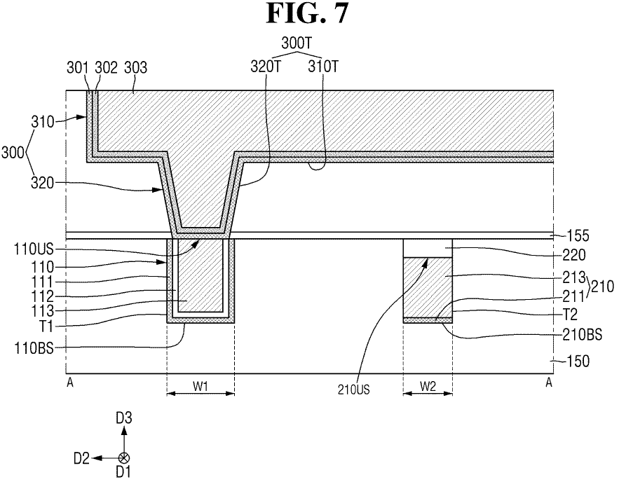

Referring to FIG. 7 as compared to FIG. 6, the first wiring structure 110 may have a liner film 112.

The liner film 112 may be placed on the first barrier film 111. The liner film 112 may extend on the first barrier film 111 along the sidewall and bottom surface of the first trench T1.

The liner film 112 may be placed between the first barrier film 111 and the first filling film 113. The upper surface of the liner film 112 is shown, but is not limited to, as being placed on the same plane as the upper surface of the first filling film 113 and the upper surface of the first barrier film 111. Here, the upper surface of the liner film 112 may mean the highest surface of a portion of the liner film 112 that extends along the sidewall of the first trench T1.

The liner film 112 includes a conductive material and may include, for example, a metal or a metal alloy. The liner film 112 may include, for example, at least one of ruthenium (Ru), cobalt (Co), and ruthenium-cobalt (RuCo) alloys.

The first filling film 113 may be placed on the first barrier film 111 and the liner film 112 inside the first trench T1. The first filling film 113 may fill the remaining portion other than the region in which the first barrier film 111 and the liner film 112 are placed inside the first trench T1.

The lower capping film 114 may be placed on the upper surface of the liner film 112. However, example embodiments are not limited thereto, and the lower capping film 114 may not cover or may only partially cover the upper surface of the liner film 112.

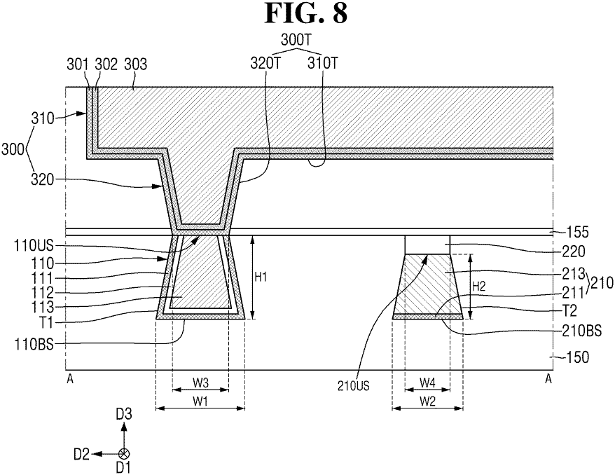

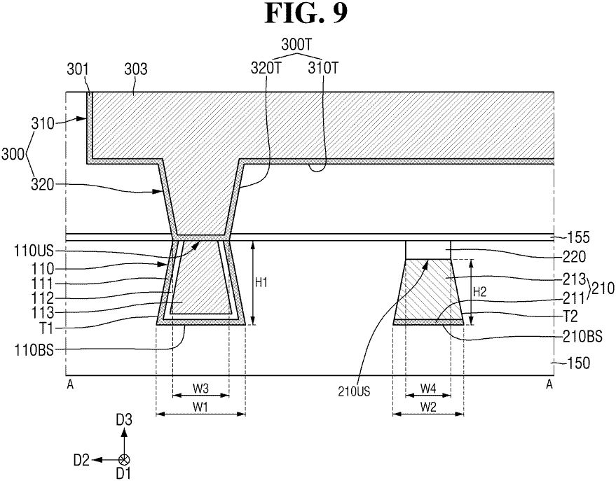

Referring to FIG. 8 as compared to FIG. 2, the first wiring structure 110 has a trapezoidal cross section, and may include a liner film 112. The liner film 112 may be placed on the first barrier film 111 along the first barrier film 111.

Referring to FIG. 9 as compared to FIGS. 5 to 8, the upper wiring structure 300 may not include the upper liner 302. The upper filling film 303 may be placed on the upper barrier film 301.

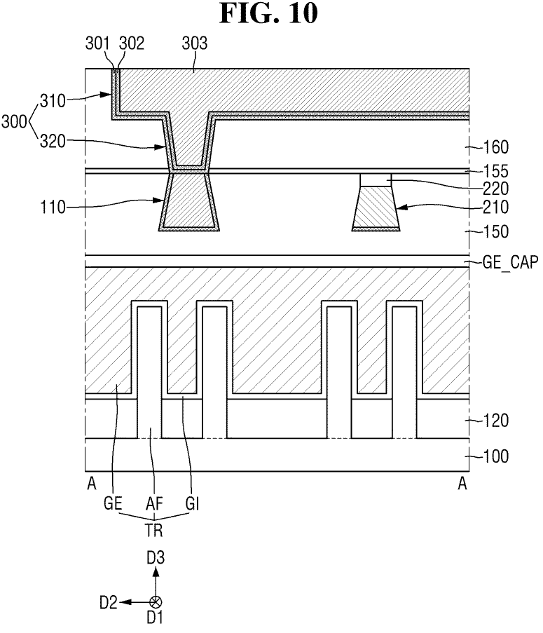

FIG. 10 is a diagram for explaining the semiconductor device according to some example embodiments. For convenience of explanation, the points different from those described referring to FIGS. 1 to 4 will be mainly described.

For reference, FIG. 10 schematically shows a part that is taken along the first gate electrode GE.

Although FIG. 10 shows that a fin-type pattern AF extends in the first direction D1 and the first gate electrode GE extends in the second direction D2, various example embodiments are not limited thereto.

Referring to FIG. 10, the semiconductor device according to some example embodiments may include a transistor TR that is placed between the substrate 100 and the first wiring structure 110, and between the substrate 100 and the second wiring structure 210.

The substrate 100 may be or may include a silicon substrate or a silicon-on-insulator (SOI). In contrast, the substrate 100 may include, but is not limited to, one or more of silicon germanium, SGOI (silicon germanium on insulator), indium antimonide, lead tellurium compounds, indium arsenic, indium phosphide, gallium arsenide or gallium antimonide. The substrate 100 may be doped, e.g. may be lightly doped with boron (B); however, example embodiments are not limited thereto.

The transistor TR may include a fin-type pattern AF, a first gate electrode GE on the fin-type pattern AF, and a first gate insulating film GI between the fin-type pattern AF and the first gate electrode GE.

Although not shown, the transistor TR may include source/drain patterns placed on either side of the first gate electrode GE.

The fin-type pattern AF may protrude from the substrate 100. The fin-type pattern AF may extend long in the first direction D1. The fin-type pattern AF may be a part of the substrate 100, or may include an epitaxial layer that is grown from the substrate 100. The fin-type pattern AF may include, for example, silicon or germanium, which is an elemental semiconductor material. Further, the fin-type pattern AF may include a compound semiconductor, and may include, for example, an IV-IV group compound semiconductor and/or a III-V group compound semiconductor.

The group IV-IV compound semiconductor may include, for example, a binary compound or a ternary compound including at least two or more of carbon (C), silicon (Si), germanium (Ge) and tin (Sn), or a compound obtained by doping these elements with a group IV element. The group III-V compound semiconductor may be, for example, at least one of a binary compound, a ternary compound or a quaternary compound formed by combining at least one of aluminum (Al), gallium (Ga) and indium (In) as a group III element with one of phosphorus (P), arsenic (As) and antimony (Sb) as a group V element.

The field insulating film 120 may be formed on the substrate 100. The field insulating film 120 may be formed on a part of the sidewall of the fin-type pattern AF. The fin-type pattern AF may protrude upward from the upper surface of the field insulating film 120. The field insulating film 120 may include, for example, an oxide film, a nitride film, an oxynitride film, or a combination film thereof.

The first gate electrode GE may be placed on the fin-type pattern AF. The first gate electrode GE may extend in the second direction D2. The first gate electrode GE may intersect the fin-type pattern AF, e.g. may intersect at right angles.

The first gate electrode GE may include, for example, at least one of a metal, a conductive metal nitride, a conductive metal carbonitride, a conductive metal carbide, a metal silicide, a doped semiconductor material, a conductive metal oxynitride, and a conductive metal oxide.

The first gate insulating film GI may be placed between the first gate electrode GE and the fin-type pattern AF, and between the first gate electrode GE and the field insulating film 120. The first gate insulating film GI may include, for example, one or more of a silicon oxide, a silicon oxynitride, a silicon nitride, or a high dielectric constant material having a dielectric constant greater than silicon oxide. The high dielectric constant material may include, for example, at least one of boron nitride, metal oxide, and metal silicon oxide.

The semiconductor device according to various example embodiments may include an NC (Negative Capacitance) FET that uses a negative capacitor. For example, the first gate insulating film GI may include a ferroelectric material film having ferroelectric properties, and a paraelectric material film having paraelectric properties.

The ferroelectric material film may have a negative capacitance, and the paraelectric material film may have a positive capacitance. For example, when two or more capacitors are connected in series, and the capacitance of each capacitor has a positive value, the entire capacitance decreases from the capacitance of each individual capacitor. On the other hand, when at least one of the capacitances of two or more capacitors connected in series has a negative value, the entire capacitance may be greater than an absolute value of each individual capacitance, while having a positive value.

When the ferroelectric material film having the negative capacitance and the paraelectric material film having the positive capacitance are connected in series, the overall capacitance values of the ferroelectric material film and the paraelectric material film connected in series may increase. By the use of the increased overall capacitance value, a transistor including the ferroelectric material film may have a subthreshold swing (SS) of 60 mV/decade or less at room temperature.

The ferroelectric material film may have ferroelectric properties. The ferroelectric material film may include, for example, at least one of hafnium oxide, hafnium zirconium oxide, barium strontium titanium oxide, barium titanium oxide, and lead zirconium titanium oxide. Here, as an example, the hafnium zirconium oxide may be a material obtained by doping hafnium oxide with zirconium (Zr). As another example, the hafnium zirconium oxide may be a compound of hafnium (Hf), zirconium (Zr), and oxygen (O).

The ferroelectric material film may further include a doped dopant. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and tin (Sn). The type of dopant included in the ferroelectric material film may vary, depending on which type of ferroelectric material is included in the ferroelectric material film.

When the ferroelectric material film includes hafnium oxide, the dopant included in the ferroelectric material film may include, for example, at least one of gadolinium (Gd), silicon (Si), zirconium (Zr), aluminum (Al), and yttrium (Y).

When the dopant is aluminum (Al), the ferroelectric material film may include 3 to 8 at% (atomic %) aluminum. Here, a ratio of the dopant may be a ratio of aluminum to the sum of hafnium and aluminum.

When the dopant is silicon (Si), the ferroelectric material film may include 2 to 10 at% silicon. When the dopant is yttrium (Y), the ferroelectric material film may include 2 to 10 at% yttrium. When the dopant is gadolinium (Gd), the ferroelectric material film may include 1 to 7 at% gadolinium. When the dopant is zirconium (Zr), the ferroelectric material film may include 50 to 80 at% zirconium.

The paraelectric material film may have paraelectric properties. The paraelectric material film may include at least one of, for example, a silicon oxide and a metal oxide having a high dielectric constant. The metal oxide included in the paraelectric material film may include, for example, but is not limited to, at least one of hafnium oxide, zirconium oxide, and aluminum oxide.

The ferroelectric material film and the paraelectric material film may include the same material. The ferroelectric material film has the ferroelectric properties, but the paraelectric material film may not have the ferroelectric properties. For example, when the ferroelectric material film and the paraelectric material film include hafnium oxide, a crystal structure of hafnium oxide included in the ferroelectric material film is different from a crystal structure of hafnium oxide included in the paraelectric material film.

The ferroelectric material film may have a thickness having the ferroelectric properties. A thickness of the ferroelectric material film may be, but is not limited to, for example, 0.5 to 10 nm. Since a critical thickness that exhibits the ferroelectric properties may vary for each ferroelectric material, the thickness of the ferroelectric material film may vary depending on the ferroelectric material.

In some examples, the first gate insulating film GI may include a single ferroelectric material film. In another example, the first gate insulating film GI may include a plurality of ferroelectric material films spaced apart from each other. The first gate insulating film GI may have a stacked film structure in which a plurality of ferroelectric material films and a plurality of paraelectric material films are alternately stacked.

A gate capping pattern GE_CAP may be placed on the first gate electrode GE. The first wiring structure 110 and the second wiring structure 210 may be placed on the first gate electrode GE. Although the first wiring structure 110 and the second wiring structure 210 are shown as not being connected to the first gate electrode GE, example embodiments are not limited thereto. One of the first wiring structure 110 and the second wiring structure 210 may be connected to the first gate electrode GE.

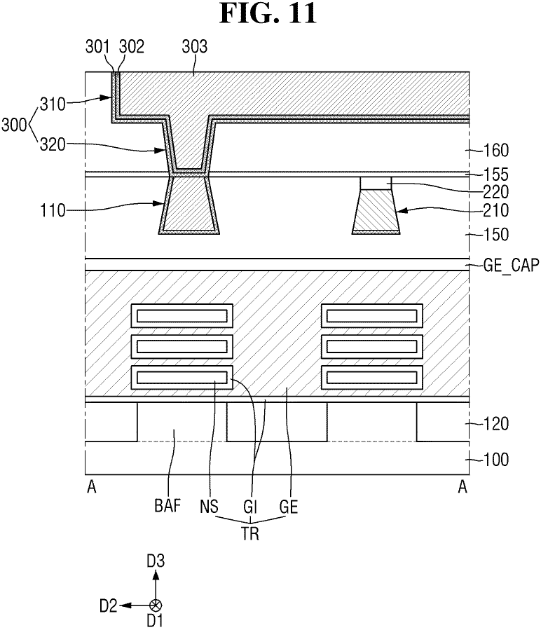

FIG. 11 is a diagram for explaining the semiconductor device according to some example embodiments. For convenience of explanation, the points different from those described referring to FIG. 10 will be mainly described.

Referring to FIG. 11, in a semiconductor device according to some example embodiments, the transistor TR may include a nanosheet NS, a first gate electrode GE that encloses the nanosheet NS, and a first gate insulating film GI between the nanosheet NS and the first gate electrode GE.

The nanosheet NS may be placed on the lower fin-type pattern BAF. The nanosheet NS may be spaced apart from the lower fin-type pattern BAF in the third direction D3. The transistor TR is shown as including, but is not limited to, three nanosheets NS spaced apart from each other in the third direction D3. The number of nanosheets NS placed in the third direction D3 on the lower fin-type pattern BAF may be more than three and may be less than three.

The lower fin-type pattern BAF and the nanosheet NS may each include silicon or germanium, which are elemental semiconductor materials. The lower fin-type pattern BAF and the nanosheet NS may each include a compound semiconductor, and may include, for example, a group IV-IV compound semiconductor or a group III-V compound semiconductor. The lower fin-type pattern BAF and the nanosheet NS may include the same material or may include different materials.

FIGS. 12 to 24 are intermediate step diagrams for explaining a method for fabricating a semiconductor device according to some example embodiments. For reference, FIGS. 12 to 24 are example diagrams showing the formation of the first wiring structure 110 and the second wiring structure 210.

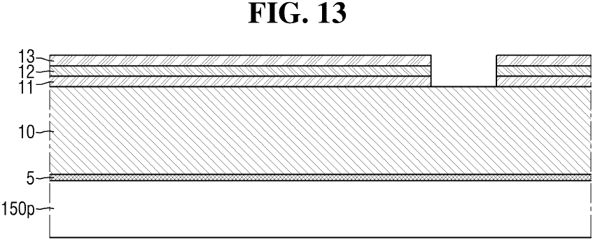

Referring to FIGS. 12 and 13, a barrier layer 5, a material film 10, a first pattern layer 11, a second pattern layer 12, a third pattern layer 13 and a mask M are sequentially formed on the pre-interlayer insulating film 150p, for example with an atomic layer deposition (ALD) and/or a chemical vapor deposition (CVD) process, and the first pattern layer 11, the second pattern layer 12, and the third pattern layer 13 are patterned, using the mask M. The material film 10 may include ruthenium (Ru); however, example embodiments are not limited thereto.

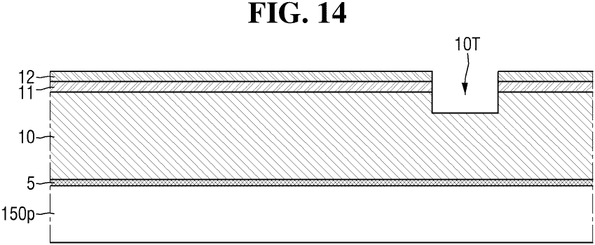

Referring to FIG. 14, the patterned first pattern layer 11, the second pattern layer 12, and the third pattern layer 13 are additionally or at least partially etched to remove the third pattern layer 13, and form the trench 10T in the material film 10, the pattern layer 11 and the second pattern layer 12.

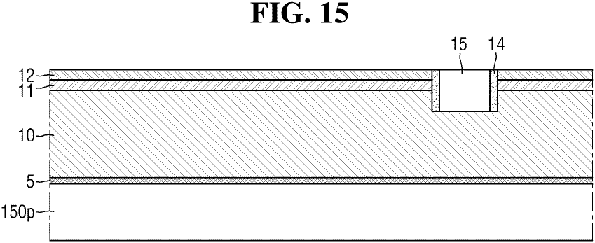

Referring to FIG. 15, a spacer film 14 and a sacrificial filling film 15 are formed in the trench 10T, e.g. with a conformal deposition process such as a CVD process.

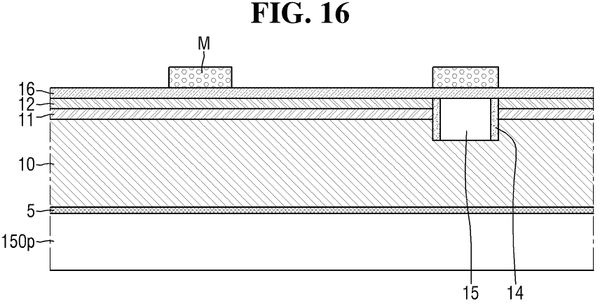

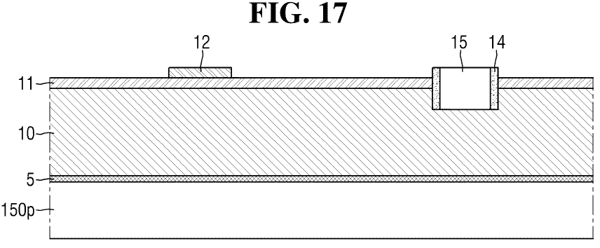

Referring to FIGS. 16 and 17, a fourth pattern layer 16 and a mask M are formed on the spacer film 14, the sacrificial filling film 15, the material film 10, the first pattern layer 11 and the second pattern layer 12, and the second pattern layer 12 is patterned, using the mask M and the fourth pattern layer 16.

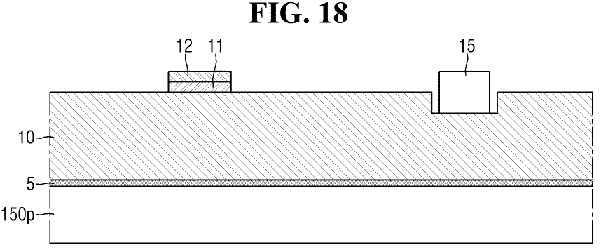

Referring to FIG. 18, the spacer film 14 is removed, and the first pattern layer 11 is patterned, using the patterned second pattern layer 12.

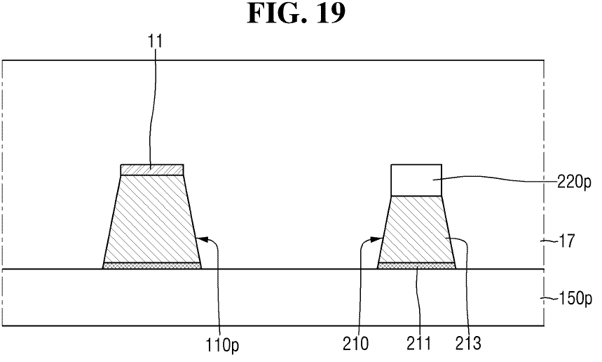

Referring to FIG. 19, the material film 10 and the barrier layer 5 are patterned using the patterned first pattern layer 11 and the sacrificial filling film 15 to form a pre-first wiring structure 110p and a pre-second wiring structure 210p including the second barrier film 211. During patterning of the material film 10, there may be at least a partially isotropic etching of the material film 10, which may lead to a trapezoidal cross-section.. The isotropic etching may include a wet etching process and/or a dry etching process. Subsequently, the insulating film 17 is formed on the pre-first wiring structure 110p and the pre-second wiring structure 210p.

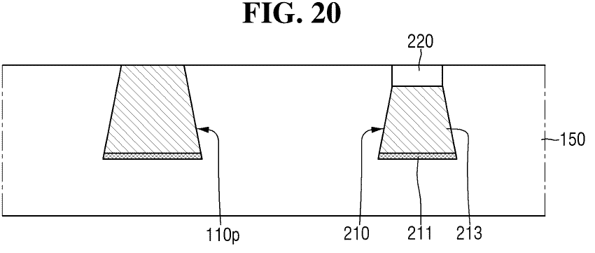

Referring to FIG. 20, the first pattern layer 11 is removed, and a part of the insulating film 17 is removed to form the interlayer insulating film 150. The pre-wiring capping film 220p is partially removed to form the second wiring structure 210 in which the wiring capping film 220 is formed.

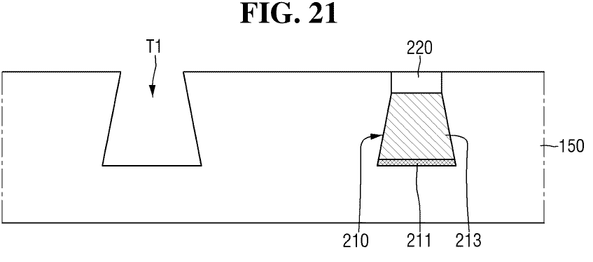

Referring to FIGS. 21 to 23, the first wiring structure 110p is removed to form the first trench T1 (for example with a wet etching process), the first barrier film 150 is formed inside the first trench T1 and on the interlayer insulating film 150, and the pre-first filling film 113p is formed on the first barrier film 111. The pre-first filing film 113p may include copper (cu) and may not include ruthenium (Ru); however, example embodiments are not limited thereto.

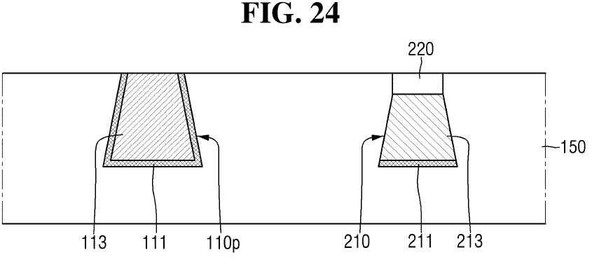

Referring to FIG. 24, a part of the first barrier film 111 and a part of the pre-first filling film 113p placed above the interlayer insulating film 150 are removed, for example with a removal process such as a chemical mechanical planarization (CMP) process, to form the first filling film 113, and the first wiring structure 110 is formed.

According to some example embodiments, a semiconductor device may be fabricated in a manner to have neighboring metal lines with different material properties. For example, a first metal line may include copper, and a second metal line may include ruthenium. There may be an improvement in resistivity and/or reliability with various example embodiments.

In concluding the detailed description, those of ordinary skill in the art will appreciate that many variations and modifications may be made to various example embodiments without substantially departing from the principles of various example embodiments. Therefore, various example embodiments are used in a generic and descriptive sense only and not for purposes of limitation. Furthermore example embodiments are not necessarily mutually exclusive with one another. For example, some example embodiments may include one or more features described with reference to one or more figures, and may also include one or more other features described with reference to one or more other figures.

1. A semiconductor device comprising:
a first wiring structure which includes a first material, and has a first width in a first direction, the first width on a lowest surface of the first wiring structure; and
a second wiring structure which includes a second material, is spaced apart from the first wiring structure in the first direction, and has a second width in the first direction that is less than the first width, the second width on a lowest surface of the second wiring structure
wherein a highest surface of the first wiring structure has a third width in the first direction that is less than the first width, and
a highest surface of the second wiring structure has a fourth width in the first direction that is less than the second width.

2. The semiconductor device of claim 1, further comprising:
a wiring capping film on the second wiring structure,
the highest surface of the wiring capping film and the highest surface of the first wiring structure are coplanar.

3. The semiconductor device of claim 1, wherein the highest surface of the second wiring structure is lower than the highest surface of the first wiring structure.

4. The semiconductor device of claim 1, wherein the first material includes copper (Cu) and the second material includes ruthenium (Ru).

5. The semiconductor device of claim 1, wherein a lowest surface of the first wiring structure and a lowest surface of the second wiring structure are coplanar.

6. The semiconductor device of claim 1, further comprising:
an upper wiring line on the first wiring structure and the second wiring structure and extending in the first direction; and
an upper via on the first wiring structure, and connecting the first wiring structure with the upper wiring line.

7. The semiconductor device of claim 1, wherein the first wiring structure includes
a barrier film, and
a filling film on the barrier film,
wherein the filling film includes the first material.

8. The semiconductor device of claim 1, wherein the first wiring structure includes a barrier film on a side part, and
the second wiring structure does not include barrier film on a side part.

9. The semiconductor device of claim 1, wherein the first wiring structure and the second wiring structure extend in a second direction intersecting the first direction.

10. The semiconductor device of claim 1, further comprising:
an interlayer insulating film on the first wiring structure and the second wiring structure,
wherein a highest surface of the first wiring structure is coplanar with an upper surface of the interlayer insulating film, and
a highest surface of the second wiring structure is below the upper surface of the interlayer insulating film.

11. A semiconductor device comprising:
a first wiring structure which includes a first material, and has a first width in a first direction on a lowest surface;
a second wiring structure which includes a second material, is spaced apart from the first wiring structure in the first direction, and has a second width in the first direction less than the first width on a lowest surface; and
an upper via connected with the first wiring structure,
wherein the lowest surface of the first wiring structure and the lowest surface of the second wiring structure are coplanar, and
a highest surface of the first wiring structure is above a highest surface of the second wiring structure.

12. The semiconductor device of claim 11, wherein the first material includes copper (Cu), and the second material includes ruthenium (Ru).

13. The semiconductor device of claim 11, further comprising:
a wiring capping film on the highest surface of the second wiring structure.

14. The semiconductor device of claim 11, wherein the highest surface of the first wiring structure has a third width in the first direction that is smaller than the first width, and
the highest surface of the second wiring structure has a fourth width in the first direction that is less than the second width.

15. The semiconductor device of claim 11, wherein
a width of the first wiring structure in the first direction decreases going away from the lowest surface of the first wiring structure, and
a width of the second wiring structure in the first direction decreases going away from the lowest surface of the second wiring structure.

16. The semiconductor device of claim 11, further comprising:
an interlayer insulating film on the first wiring structure and the second wiring structure, wherein the first wiring structure includes
a barrier film,
a liner film placed on the barrier film, and
a filling film on the liner film and including the first material.

17. A semiconductor device comprising:
an interlayer insulating film defining a first trench and a second trench, a width of a bottom surface of the first trench being smaller than a width of a bottom surface of the second trench;
a first wiring structure inside the first trench and including an upper surface coplanar with an upper surface of the interlayer insulating film; and
a second wiring structure placed inside the second trench and including an upper surface lower than the upper surface of the interlayer insulating film,
wherein a width of the bottom surface of the first trench is greater than a width of a highest part of the first trench, and
a width of the bottom surface of the second trench is greater than a width of a highest part of the second trench.

18. The semiconductor device of claim 17, wherein the first wiring structure includes,
a first barrier film extending along a sidewall and the bottom surface of the first trench, and
a first filling film on the first barrier film that fills the first trench.

19. The semiconductor device of claim 17, wherein the second wiring structure includes,
a second barrier film which extends along the bottom surface of the second trench and does not extend along a sidewall of the second trench, and
a second filling film on the second barrier film.

20. The semiconductor device of claim 19, further comprising:
a wiring capping film on the upper surface of the second wiring structure,
wherein the upper surface of the wiring capping film is coplanar with the upper surface of the interlayer insulating film.

21. (canceled)
